(19) United States
(12) Patent Application Publication
(10) Pub. No.: US 2012/0248417 A1
(43) Pub. Date: Oct. 4, 2012

(54) DOUBLE GATE NANOSTRUCTURE FET

(75) Inventors: Bart Soree, Begijnendijk (BE); Wim Magnus, O.L.V.-Waver (BE)

(73) Assignee: IMEC, Leuven (BE)

(21) Appl. No.: 13/514,941

(22) PCT Filed: Dec. 21, 2009
(86) PCT No.: PCT/EP2009/067648

§ 371 Date: Jun. 8, 2012

(51) Int. Cl. H01L 29/78; B82Y 99/00

(52) U.S. Cl. 257/29; 257/E29.255; 977/938

(57) ABSTRACT

A Field Effect Transistor (FET) semiconductor device comprising at least one nanostructure, comprises at least a uniformly doped beam-shaped nanostructure having two major surfaces, a gate electrode provided at either major surface of the nanostructure, and an insulating layer between each of the major surfaces of the nanostructure and the gate electrodes to form a double gate nanostructure pinch-off FET. It is an advantage of such FET that pinch-off voltage and current of the FET can be independently tuned.

### CROSS-REFERENCE TO RELATED APPLICATIONS

This application is the national phase under 35 U.S.C. §371 of prior PCT International Application No. PCT/EP2009/067648 which has an International Filing Date of Dec. 21, 2009, the disclosure of which is hereby expressly incorporated by reference in its entirety and is hereby expressly made a portion of this application.

### FIELD OF THE INVENTION

The present invention relates to the field of semiconductor devices comprising nanostructures.

More particularly, the present invention relates to a novel device architecture namely a double gate nanostructure pinch-off FET (DG nano PO FET) which is able to considerably weaken surface roughness effects in the nanostructure.

### BACKGROUND OF THE INVENTION

Microelectronic devices are generally fabricated on semiconductor substrates as integrated circuits. A complementary metal-oxide-semiconductor (CMOS) field effect transistor (FET) is one of the core elements of the integrated circuits. Dimensions and operating voltages of CMOS transistors are continuously reduced, or scaled down, to obtain ever-higher performance and packaging density of the integrated circuits.

To further sustain this trend, novel nanostructures such as nanowires are explored as possible successors of the current state-of-art silicon devices.

However as nanowires are scaled down to smaller radii, the interaction of electrons with the surface of the nanowire becomes important and due to surface roughness of the nanowire this will become detrimental for the device performance due to mobility degradation.

As a result, surface roughness or high-k scattering becomes a dominant scattering mechanism that may depress the carrier mobility significantly, thus rendering nanowires inadequate for MOSFET operation.

This problem of reduced mobility in small radii nanostructures due to sidewall (surface) roughness has been solved by providing a surrounding gate nanostructure which is operated not in the MOSFET mode but in the JFET mode, as described in U.S. Ser. No. 12/246,270, Nanostructure insulated junction field effect transistor. Said nanostructure is thereby surrounded by an insulating layer with a surrounded gate on top of said insulating layer, wherein both the source and the drain as well as the body of the nanostructure are uniformly doped. Such nano-JFET makes it possible to push the majority carriers (electrons) to the middle of the nanostructure when a negative gate voltage (called pinch-off voltage) is applied. In this case the nanostructure is in the OFF-state because there are no majority carriers present to conduct the current. For gate voltages larger than the pinch-off voltage, the nanostructure conducts current carried by the majority carriers supplied by the ionized donors in the channel. For a flat band gate voltage the nanostructure conducts current throughout the entire volume of the channel. Because the majority of the carriers are residing not at the surface such as in a MOSFET, but are instead distributed throughout the entire volume, surface roughness scattering plays a less prominent role.

It is a disadvantage of the above gate-all-around nanostructure that the pinch-off gate voltage depends on the wire radius. In order to obtain a reasonable pinch-off gate voltage, and in the applications where such nanowire FETS are use this means below 1V, the radius of the nanowire is restricted, thus the cross-section is restricted too. However, if the radius is small, then the nanostructure can carry only a limited current (total current is limited for a given current density). The allowable current density can be increased by providing a higher dopant concentration to the nanostructure, but this would also make the pinch-off voltage increase, which is not desirable.

As a conclusion, there is still a need for an improved FET design.

### SUMMARY OF THE INVENTION

It is an object of embodiments of the present invention to provide a novel architecture for a semiconductor Field Effect Transistor (FET) made of nanostructures, having a pinch-off gate voltage below 1 V and at the same time a current which can be higher than the current in prior art nano JFETS.

The above objective is accomplished by a device according to the present invention.

According to a first embodiment of the present invention, a Field Effect Transistor (FET) semiconductor device is provided, comprising at least one nanostructure. Said FET comprises at least
a uniformly doped beam-shaped nanostructure having two major surfaces,
a gate electrode provided at either major surface of the nanostructure, and
an insulating layer between each of the major surfaces of the nanostructure and the gate electrodes to form a double gate nanostructure pinch-off FET.

It is an advantage of such FET according to the first embodiment of the present invention that it works according to the pinch-off principle. In embodiments of the present invention, pinch-off voltage and current of the FET can be independently tuned.

In Field Effect Transistor semiconductor devices according to embodiments of the present invention, the insulating layers at least partially cover the nanostructure such that the gate electrodes make no direct contact to the nanostructure. By not making contact between the gate electrodes and the nanostructure, gate leakage is avoided.

In a Field Effect Transistor semiconductor device according to embodiments of the present invention, the nanostructure may be a uniformly doped nanostructure.

In a Field Effect Transistor semiconductor device according to embodiments of the present invention, the nanostructure may be made from semiconductor material such as for example Si, Ge, GaAs, InGaAs.

In a Field Effect Transistor semiconductor device according to embodiments of the present invention, the insulating layers may be oxide layers.

In a Field Effect Transistor semiconductor device according to embodiments of the present invention, the gate electrodes may be made of a conductive material with a workfunction between 3 and 5. The workfunction of the gate electrodes determines the pinch-off voltage and the flat band voltage.

In a Field Effect Transistor semiconductor device according to embodiments of the present invention, the nanostructure may have a first length, a width and a thickness. The thickness and doping level of the nanostructure determine the pinch-of voltage of the FET, while the width determines the current that is allowed to flow through the device. Hence it can be seen that pinch-off voltage and current can be independently tuned.

In a Field Effect Transistor semiconductor device according to embodiments of the present invention, the gate electrodes may have a second length in a same direction as the first length of the nanostructure, the second length being not larger than the first length. The insulating layers may have a third length in a same direction as the second length, the third length not being smaller than the second length. This way, gate leakage is avoided.

Particular and preferred aspects of the invention are set out in the accompanying independent and dependent claims. Features from the dependent claims may be combined with features of the independent claims and with features of other dependent claims as appropriate and not merely as explicitly set out in the claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 is a schematic 3D view of a double gate nanostructure pinch-off FET (DG nano PO FET) according to embodiments of the present invention.

FIG. 2 is a longitudinal cross-sectional view of the DG nano PO FET illustrated in FIG. 1.

FIG. 3 to FIG. 5 illustrate schematic representations of the band bending in an N-type DG nano PO FET according to embodiments of the present invention when a zero or negative gate voltage is applied (FIG. 4 and FIG. 5 illustrate different negative gate voltages).

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

According to embodiments of the present invention, a novel nanostructure device architecture is set up such that the advantages of using such nanostructure devices, such as for example outstanding electrostatic control, can be fully exploited with a strongly reduced interaction of electrons at the surface (e.g. due to surface roughness) leading to unwanted decrease in mobility. According to particular embodiments described below it is found that by combining the advantages of a “JFET operation” mode with a “MOSFET operation” mode a unique device operation is achieved whereby surface interactions are reduced because in the ON-state the majority carriers are distributed throughout the entire volume of the nanostructure (JFET operation) by using a double gate electrode. In embodiments of the present invention gate leakage is avoided by using an insulation layer in between the double gate electrode and the nanostructure (MOSFET operation). This device architecture is further referred to as a double gate nanostructure pinch-off Field Effect Transistor (DG nano PO FET).

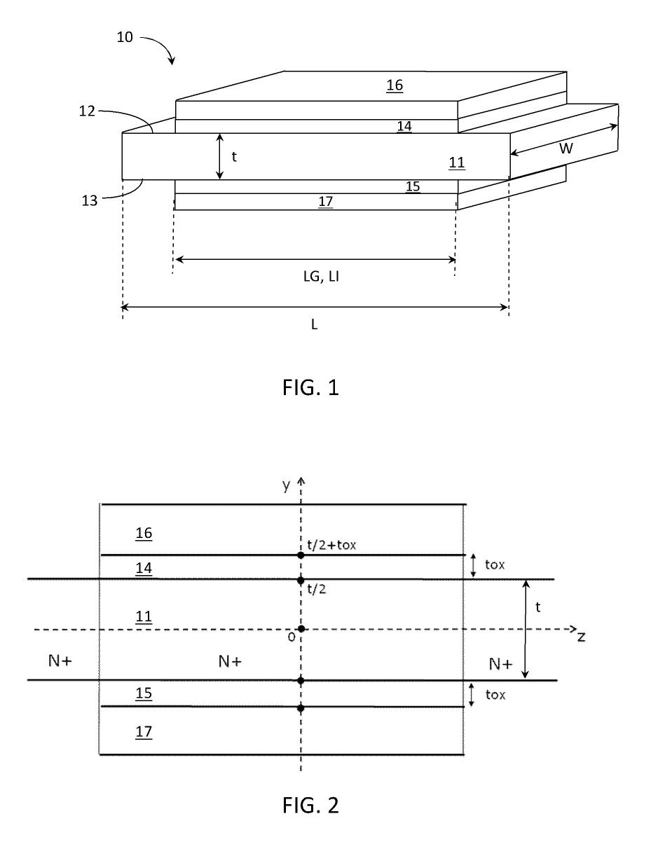

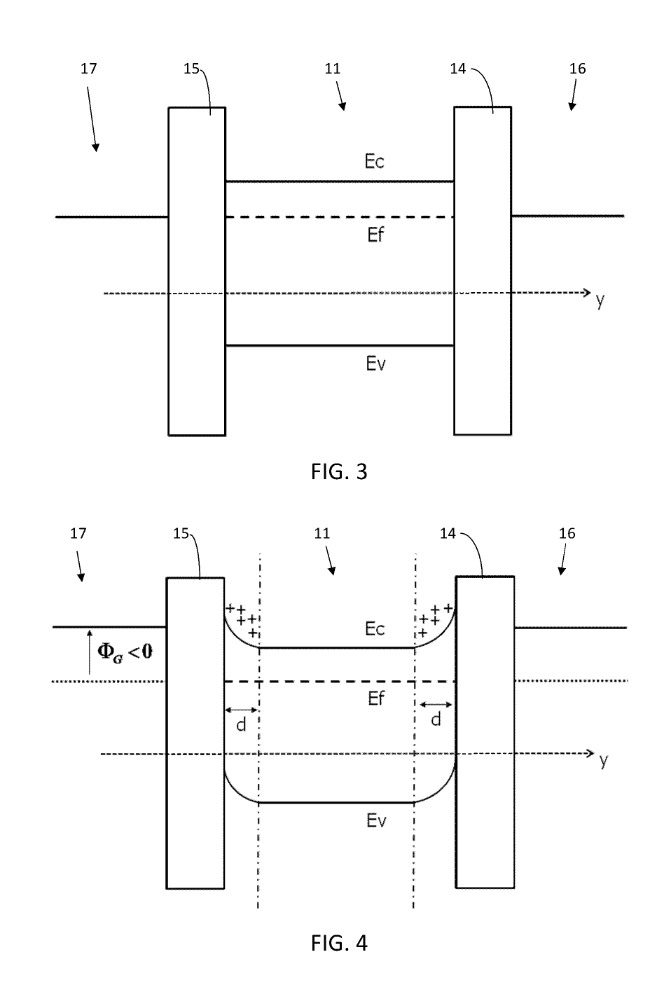

FIG. 1 illustrates a schematic representation of a 3D view of a DG nano PO FET 10 according to embodiments of the present invention. FIG. 2 illustrates a cross-section along its longitudinal direction of the DG nano PO FET 10 of FIG. 1.

The DG nano PO FET 10 comprises a nanostructure 11 of a first dopant type, e.g. an N+ doped nanostructure. In embodiments of the present invention the nanostructure 11 is a uniformly doped nanostructure. In particular embodiments of the present invention the nanostructure 11 is beam shaped with length L, width W and thickness t. The nanostructure 11 comprises two major surfaces 12, 13, and is provided at either of these surfaces with an insulating layer 14, 15. The insulating layers 14, 15 have a thickness tox. On top of both insulating layers 14, 15 a gate electrode 16, 17 is provided. The gate electrodes 16, 17 each have a length LG. The insulating layers 14, 15 have a length LI, which is not smaller than the length LG of the gate electrodes 16, 17 so that gate leakage is avoided. In the embodiment illustrated in FIG. 1 and FIG. 2, the length LI of the insulating layers 14, 15 is substantially equal to the length LG of the gate electrodes 16, 17. In particular embodiments of the present invention, the insulating layers 14, 15 cover the nanostructure 11 along its whole length L in longitudinal direction. The gate electrodes 16, 17 and the insulating layers 14, 15 are positioned which respect to the conductive layer 11 such that the gate electrodes 16, 17 are isolated from the nanostructure 11 by means of the insulating layers 14, 15. The insulating layers 14, 15 are covering the nanostructure 11 along its longitudinal direction such that the gate electrodes 16, 17 make no direct contact to the nanostructure 11.

Typical dimensions of LG, LI and L may be between 10 nm and 1 micron, t may be between 5 and 100 nm, and W may be in a range between 5 nm up to several microns.

According to particular embodiments the nanostructure 11 is uniformly doped with a donor density ND, whereby ND is in the range of 10¹⁶ cm⁻³-10²⁰ cm⁻³, for example said ND may be in the range of 10¹⁸ cm⁻³-10²⁰ cm⁻³.

According to particular embodiments the uniformly doped nanostructure 11 is an N-type or P-type doped nanostructure, more preferably the N-type or P-type doped nanostructure 11 may an N-type or P-type doped nanostructure made of a semiconductor material such as Si, Ge, or III-V semiconductor materials, such as for example GaAs or InGaAs.

According to particular embodiments the insulating layers 14, 15 used to isolate the gate electrodes 16, 17 from the nanostructure 11 may be made of an oxide layer e.g. SiO2. During device operation, said insulating layers 14, 15 are crucial for preventing gate leakage in the DG nano PO FET 10.

According to particular embodiments the gate electrodes 16, 17 are made of a conductive material with a workfunction between 3 and 5.

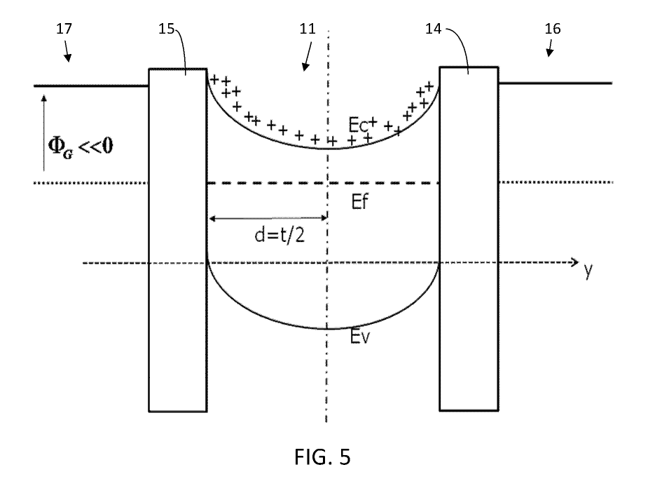

FIG. 3 to FIG. 5 illustrate schematic representations of the band bending in an N-type DG nano PO FET of embodiments of the present invention when a negative gate voltage is applied (FIG. 4 to FIG. 6 illustrate different negative gate voltages). Similar graphs (not illustrated in the drawings) are within the reach of a person skilled in the art for the band bending in a P-type DG nano PO FET of embodiments of the present invention when a positive gate voltage is applied.

If the gate voltage applied to the double gate structure according to embodiments of the present invention is set to zero (flatband situation, illustrated in FIG. 3), majority carriers are present everywhere in the channel. The channel is fully open. If a source-drain voltage is applied, the nanostructure 11 is fully conducting a current carried by the majority carriers, in the example described electrons.

Applying a negative gate voltage to the N-type double gate structure according to embodiments of the present invention pushes the majority carriers, in this example electrons, away from the interface, leaving behind positively charged ions, as illustrated in FIG. 4. Applying a negative gate voltage thus partially depletes the channel. The channel is not fully open, nor is it pinched off completely. In the middle of the channel majority carriers, in the present example electrons, are still present which are delivered by the dopant donors.

For sufficient gate action, i.e. in the example described if the applied gate voltage has a sufficiently negative amplitude, such that the gate voltage equals the pinch-off voltage, the channel is pinched off. This is illustrated in FIG. 5. No majority carriers are present in the channel and no current can flow through the nanostructure 11.

The DG nano PO FET thus operates as a classical JFET (see W. Shockley, Proc. IRE, 40, p. 1365, (1952)), except for the presence of an insulators 14, 15 between the nanostructure 11 forming the channel, e.g. a silicon channel, and the gate electrodes 16, 17 which insulators 14, 15 are present to avoid excessive gate leakage.

The electrostatics of a DG nano PO FET 10 according to embodiments of the present invention are as follows.

The calculation is started with solving Poisson's equation ∇·\vec{E}=−∇²Φ=ρ/ε, where E is the electric field, while Φ is the electrostatic potential, and taking into account the charge density ρ in the channel as constructed below.

For the charge density ρ in the channel, abrupt depletion approximation is assumed, i.e. the charge density is given by:

$$ρ ( y ) = \{ \begin{matrix}{eN}_{D}^{+} & \frac{t}{2} - d \leq y \leq \frac{t}{2} \\ 0 & 0 \leq y \leq \frac{t}{2} - d\end{matrix}$$

where d is the depletion layer thickness and t is the nanostructure thickness of the double gate nano PO FET 10 under consideration, while ND+ is the dopant concentration, e.g. the number of ionized donors.

The following differential equation is obtained for the electrostatic potential profile inside the nanostructure body:

$$- \frac{{d}^{2} Φ}{d {y}^{2}} = \{ \begin{matrix}\frac{{eN}_{D}^{+}}{ɛ} & \frac{t}{2} - d \leq y \leq \frac{t}{2} \\ 0 & 0 \leq y \leq \frac{t}{2} - d\end{matrix}$$

As a result, the following general solution is obtained for the electrostatic potential:

$${Φ}_{1} ( y ) = - \frac{{eN}_{D}^{+}}{2 ɛ} {y}^{2} + Cy + D \qquad \frac{t}{2} - d \leq y \leq \frac{t}{2}$$

$${Φ}_{2} ( y ) = Ay + B \qquad 0 \leq y \leq \frac{t}{2} - d$$

The coefficients A, B, C and D are determined by imposing the usual boundary conditions:

Φ₂(0)=0

Φ′₂(0)=0

Φ₁(t/2−d)=Φ₂(t/2−d)

Φ′₁(t/2−d)=Φ′₂(t/2−d)

In the dielectric, e.g. oxide, Poisson's equation becomes:

∇·\vec{E}=−∇²Φ=0,

which yields the following general solution for the electrostatic potential in the dielectric:

$${Φ}_{ox} ( y ) = Ey + F \qquad \frac{t}{2} \leq y \leq \frac{t}{2} + {t}_{ox}$$

Also there are other boundary conditions to be met, namely

Φₒₓ(t/2)=Φ₁(t/2)

εₒₓΦ′ₒₓ(t/2)=εΦ′₁(t/2)

The electrostatic potential of the dielectric can be connected with the gate electrostatic potential by using the following boundary condition:

Φₒₓ(t/2+tₒₓ)=Φ_{G}

Combining all the boundary conditions allows to find a relation between the gate electrostatic potential and the depletion width d:

$${Φ}_{G} = - \frac{{eN}_{D}^{+}}{2 ɛ} {d}^{2} - \frac{{eN}_{D}^{+}}{{ɛ}_{ox}} d \cdot {t}_{ox}$$

This can be solved for the depletion width d:

$$d = - \frac{{t}_{ox} ɛ}{{ɛ}_{ox}} + \sqrt{{( \frac{{t}_{ox} ɛ}{{ɛ}_{ox}} )}^{2} - \frac{2 ɛ}{{eN}_{D}^{+}} {Φ}_{G}}$$

When comparing the current through a gate all-around nanowire FET and the current through a DG nano PO FET according to embodiments of the present invention, the following is found. For a nanowire pinch-off FET with a drain voltage Vd

$$I = \frac{e {μ}_{n} {N}_{D} π}{L} {\int }_{0}^{{V}_{D}} d {Ve}^{γ / α} {R}^{2} [ \frac{V - {Φ}_{G} - γ {R}^{2}}{α {e}^{γ / α} {R}^{2} W ( \frac{V - {Φ}_{G} - γ {R}^{2}}{α {e}^{γ / α} {R}^{2}} )} ]$$

where

$$α = \frac{{eN}_{D}}{4 ɛ} and γ = α + β ln \frac{R + {t}_{ox}}{R}$$

with

$$β = \frac{{eN}_{D}}{2 {ɛ}_{ox}}$$

and L the length of the nanowire FET, R the radius and W the Lambert W-function which is the inverse of the function z=we^{w} (see F. Chapeau-Blondeau et al., Numerical evaluation of the Lambert W-function and Application to Generation or Generalized Gaussian Noise with Exponent 1/2, IEEE Trans. Signal Processing, (2002) pp. 2160-2165), μₙ is the electron mobility. This equation shows that the current is proportional with the nanowire mobility and donor doping density.

For a DG nano PO FET according to embodiments of the present invention the current may be represented by:

$$I = \frac{2 e {μ}_{n} {N}_{D} W}{L} {\int }_{0}^{{V}_{d}} d V ( \frac{t}{2} + δ - \sqrt{{δ}^{2} - β ( {Φ}_{G} - V )} )$$

where W is the width, L the length, while

$$δ = \frac{{t}_{ox} ɛ}{{ɛ}_{ox}} and β = \frac{2 ɛ}{{eN}_{D}^{+}} .$$

Hence the current I is proportional to the width W of the nanostructure. This equation shows that, in embodiments of the present invention, the current is proportional with the nanostructure mobility, with the donor doping density and with the width of the nanostructure 11.

The pinch-off gate voltage in a DG nano PO FET according to embodiments of the present invention depends on device parameters such as for example doping level, film thickness, etc. A relation between depletion layer thickness d and applied gate voltage is given by

$$d = - \frac{{t}_{ox} {ɛ}_{ch}}{{ɛ}_{ox}} + \sqrt{{( \frac{{t}_{ox} {ɛ}_{ch}}{{ɛ}_{ox}} )}^{2} - \frac{2 {ɛ}_{ch}}{{eN}_{D}} {Φ}_{G}}$$

Complete pinch-off is achieved if the depletion layer generated by applying a suitable gate voltage to each of the gate electrodes 16, 17 has a thickness d=t/2, which yields:

$${Φ}_{G} = \frac{{eN}_{D}}{2 {ɛ}_{ch}} [ {( \frac{{t}_{ox} {ɛ}_{ch}}{{ɛ}_{ox}} )}^{2} - {( \frac{t}{2} + \frac{{t}_{ox} {ɛ}_{ch}}{{ɛ}_{ox}} )}^{2} ]$$

It is an advantage of embodiments of the present invention that the pinch-off gate voltage is determined by the substrate thickness t, but that at the same time the amount of volume or the cross-sectional area of the FET can be varied by changing the width W of the nanostructure 11. Hence more current can be carried by such DG nano PO FET 10 while still having a limited pinch-off gate voltage.

While the invention has been illustrated and described in detail in the drawings and foregoing description, such illustration and description are to be considered illustrative or exemplary and not restrictive. The invention is not limited to the disclosed embodiments.

Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to include any specific characteristics of the features or aspects of the invention with which that terminology is associated.

1-9. (canceled)

10. A field effect transistor semiconductor device comprising:
a uniformly doped beam-shaped nanostructure having a first major surface and a second major surface;
a first gate electrode at the first major surface and a second gate electrode at the second major surface;
a first insulating layer between the first major surface and the first gate electrode; and
a second insulating layer between the second major surface and the second gate electrode,
wherein the field effect transistor semiconductor device comprises a double gate nanostructure pinch-off field effect transistor.

11. The field effect transistor of claim 10, wherein the first insulating layer and the second insulating layer each at least partially cover the nanostructure, such that the first gate electrode and the second gate electrode make no direct contact with the uniformly doped beam-shaped nanostructure.

12. The field effect transistor of claim 10, wherein the uniformly doped beam-shaped nanostructure comprises a semiconductor material.

13. The field effect transistor of claim 10, wherein the first insulating layer and the second insulating layer are each an oxide layer.

14. The field effect transistor of claim 10, wherein the first gate electrode and the second gate electrode each comprise a conductive material having a workfunction of from 3 to 5.

15. The field effect transistor of claim 10, wherein the uniformly doped beam-shaped nanostructure has a first length, a width and a thickness, and wherein the first gate electrode and the second gate electrodes each have a second length in a same direction as the first length of the uniformly doped beam-shaped nanostructure, wherein the second length is not larger than the first length.

16. The field effect transistor of claim 15, wherein the first insulating layer and the second insulating layer each have a third length in a same direction as the second length, wherein the third length is not smaller than the second length.
